(19) United States
(12) Patent Application Publication
(10) Pub. No.: US 2024/0213328 A1
(43) Pub. Date: Jun. 27, 2024

(54) DIRECT ELECTROPLATING ON MODIFIED POLYMER-GRAPHENE COMPOSITES

(71) Applicant: INTEL CORPORATION, SANTA CLARA, CA (US)

(72) Inventors: Vinith BEJUGAM, Chandler, AZ (US); Yonggang LI, Chandler, AZ (US); Srinivas V. PIETAMBARAM, Chandler, AZ (US); Chandrasekharan NAIR, Mesa, AZ (US); Whitney BRYKS, Tempe, AZ (US); Gene CORYELL, Maricopa, AZ (US)

(21) Appl. No.: 18/089,494

(22) Filed: Dec. 27, 2022

(51) Int. Cl. H01L 29/16; H01L 21/768; H01L 23/00; H01L 23/31; H01L 23/48

(52) U.S. Cl. CPC H01L 29/1606; H01L 21/76898; H01L 23/3128; H01L 23/481; H01L 24/16; H01L 2924/15311

(57) ABSTRACT

Embodiments disclosed herein include a package substrate. In an embodiment, the package substrate comprises a core with a via opening through the core. In an embodiment, the via opening comprises sidewalls. In an embodiment, a composite layer is provided along the sidewalls, and the composite layer comprises carbon. In an embodiment, the package substrate further comprises a via within the via opening, where the via is electrically conductive.

### TECHNICAL FIELD

Embodiments of the present disclosure relate to electronic packages, and more particularly to packaging substrates that include conductive features that are electroplated without the use of a conventional seed layer.

### BACKGROUND

Typically, electroplating requires a precursor seed layer. Precursor seed layers a generally sufficient for planar surfaces. However, when high aspect ratio features are formed, existing seed layer deposition processes are less effective. For example, the center of high aspect ratio via openings may not be fully plated by the seed layer. This may lead to the formation of voids in the plated vias.

In some instances electroless plating is used to form the seed layer. In such instances, the surface is cleaned and activated with palladium salts. This is followed by metal deposition using a redox mechanism. The palladium and the metal together function as the seed layer for subsequent electroplating. However, palladium is an expensive chemical. Moreover, the adhesion between subsequent metal and palladium on the glass is weak. A minimum of 200 nm to 500 nm seed layer is required to enable sufficient adhesion. Also, if the underlying roughness increases, it could potentially lead to delamination.

Another option is to use physical vapor deposition (PVD) (e.g., sputtering or evaporation). Typically, the PVD process deposits a seed layer such as titanium, tungsten, ruthenium, of tantalum. However, such plating processes are expensive and offer low rates of deposition. This makes the run-rate very low. Target metal and processing gasses also have a high cost. Additionally, maintenance costs are high.

### BRIEF DESCRIPTION OF THE DRAWINGS

FIG. 1 is a cross-sectional illustration of a package substrate with through glass vias (TGVs) that are plated on an interface layer without a seed layer, in accordance with an embodiment.

FIGS. 2A-2G are cross-sectional illustrations depicting a process for forming a package substrate with TGVs that are plated on an interface layer without a seed layer, in accordance with an embodiment.

FIG. 3 is a cross-sectional illustration of a package substrate that includes dielectric buildup layers that are formed from a polymer with graphene fillers, in accordance with an embodiment.

FIGS. 4A-4E are cross-sectional illustrations depicting a process for forming a core with a conductive layer formed over a layer of carbon nanotubes that are welded to a surface of the core, in accordance with an embodiment.

FIGS. 5A-5C are cross-sectional illustrations depicting a process for forming a core with vias that are plated up from carbon nanotubes that are welded to the surface of the core, in accordance with an embodiment.

FIGS. 6A-6F are cross-sectional illustrations depicting a process for forming a core with a conductive layer plated over an interface layer that comprises a metal-alkoxide with carbon nanotube fillers, in accordance with an embodiment.

FIGS. 7A-7C are cross-sectional illustrations depicting a process for forming a core with vias that are plated on an interface layer that comprises a metal-alkoxide with carbon nanotube fillers, in accordance with an embodiment.

FIG. 8 is a cross-sectional illustration of a computing system that includes a package substrate with a core that includes TGVs that are plated on an interface layer without an intervening seed layer, in accordance with an embodiment.

FIG. 9 is a schematic of a computing device built in accordance with an embodiment.

### EMBODIMENTS OF THE PRESENT DISCLOSURE

Described herein are packaging substrates that include conductive features that are electroplated without the use of a conventional seed layer, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, seed layer formation has difficulties with providing good plating coverage of high aspect ratio features. Additionally, the plating process to form the seed layer (e.g., PVD processes, palladium salts, etc.) are expensive and may have poor adhesion strength. Accordingly, embodiments disclosed herein include interface layers that are used instead of seed layers. In an embodiment, the overlying conductive feature (e.g., a via, a pad, a trace, or the like), may be plated up directly from the interface layer. That is, there may not be an intervening seed layer in some embodiments.

In an embodiment, the interface layer may be one of several different material compositions. In one embodiment, the interface layer may comprise a polymer with graphene fillers. In another embodiment, the interface layer may be a layer of carbon nanotubes that are welded to the surface of the dielectric (e.g., a glass core). In yet another embodiment, the interface layer may be a metal-alkoxide that includes carbon nanotubes.

The graphene and/or carbon nanotubes that are provided within the interface layer have a high enough conductivity in order to allow for direct electroplating without the need for a seed layer. Additionally, the interface layers are laterally non-conducting. That is, even when a layer of the interface layer persists into the final structure, there will be no shorting between structures. In some instances the interface layer may be used as a buildup layer in the package substrate. The low filler percentage does not negatively impact dielectric properties or coefficient of thermal expansion (CTE), and allows for the interface layer to be used in place of traditional buildup films. By replacing the buildup film with the interface layer, seed layer deposition processes may be omitted from the process flow.

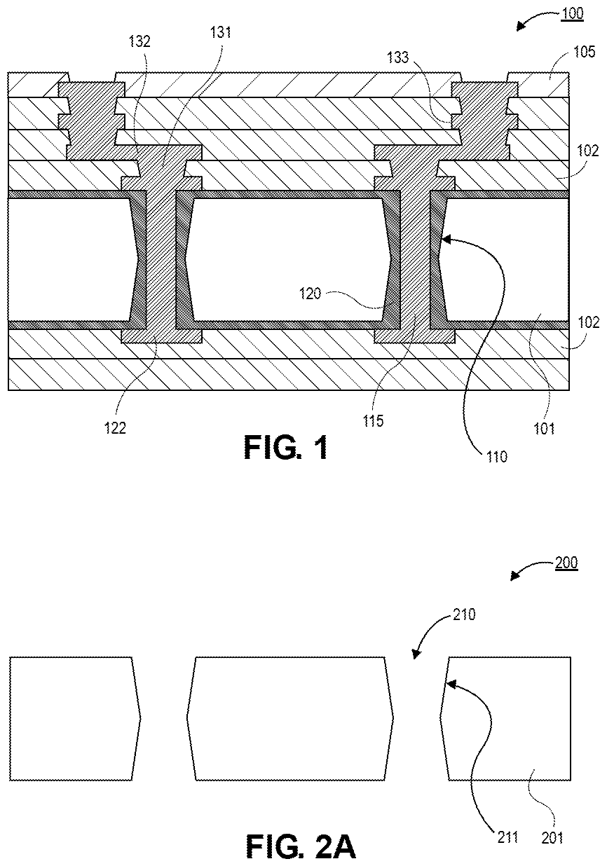

Referring now to FIG. 1, a cross-sectional illustration of a package substrate 100 is shown, in accordance with an embodiment. In an embodiment, the package substrate 100 comprises a core 101. The core 101 may be a glass core 101 or an organic core 101. For example, the glass may comprise a borosilicate glass, a fused silica glass, or the like. In an embodiment, the core 101 may have a thickness between approximately 100 μm and approximately 1,000 μm. As used herein, “approximately” may refer to a range of values that are within ten percent of the stated value. For example, approximately 100 μm may refer to a range between 90 μm and 110 μm.

In an embodiment, the core 101 may comprise a via opening 110. In an embodiment, the via opening 110 may extend through a thickness of the core 101. The via opening 110 may have sloped sidewalls. For example, the via opening 110 in FIG. 1 has sloped sidewalls that provide an hourglass shaped cross-section. As used herein, an hourglass shaped cross-section may refer to a shape that has ends that are wider than a middle of the shape. For example, the top and bottom of the via opening 110 are wider than a middle of the via opening 110.

In an embodiment, the via opening 110 may be lined with an interface layer 120. The interface layer 120 may be a material that allows for direct electroplating of a conductive feature, such as a via 115. It is to be appreciated that the interface layer 120 is different than a seed layer. For example, in the embodiment shown in FIG. 1, the interface layer 120 may be a composite material that comprises a polymer with graphene particles. In an embodiment, the graphene particles may have a weight percentage up to approximately 5 weight percent. For example, the graphene particles may have a weight percent between approximately 0.5 weight percent and approximately 5 weight percent. In an embodiment, the polymer may include any suitable polymer material. For example, the polymer may comprise one or more of a polyimide (PI), a polyethylene terephthalate (PET), a polyacetylene (PA), a polyaniline (PANi), a polypyrrole (PPy) a polythiophene (PT), a poly(p-phenylene) (PPP), a poly(3,4-ethylene dioxythiophene) (PEDOT), and the like.

In an embodiment, the inner wall of the interface layer 120 (i.e., the surface that contacts the via 115) may be substantially vertical. That is, the profile of the inner wall of the interface layer 120 may be different than the profile of the via opening 110. In an embodiment, the interface layer 120 may have a thickness between approximately 100 nm and approximately 5 μm. In an embodiment, the interface layer 120 may also be provided over a top surface and a bottom surface of the core 101. It is to be appreciated that, while allowing for electroplating, the interface layer 120 is substantially electrically insulating. This allows for the interface layer 120 to persist into the final structure of the package substrate 100 without causing electrical shorting between conductive structures (e.g., pads 122) in the core 101.

In an embodiment, the package substrate 100 may further comprise buildup layers 102 above and below the core 101. The buildup layers 102 may include a dielectric film, such as buildup film or the like. In an embodiment, conductive routing may be provided in the buildup layers 102. For example, vias 131, traces 132, and pads 133 may be provided in the buildup layers 102. In an embodiment, a solder resist 105 with openings may be provided over a top layer of the package substrate 100.

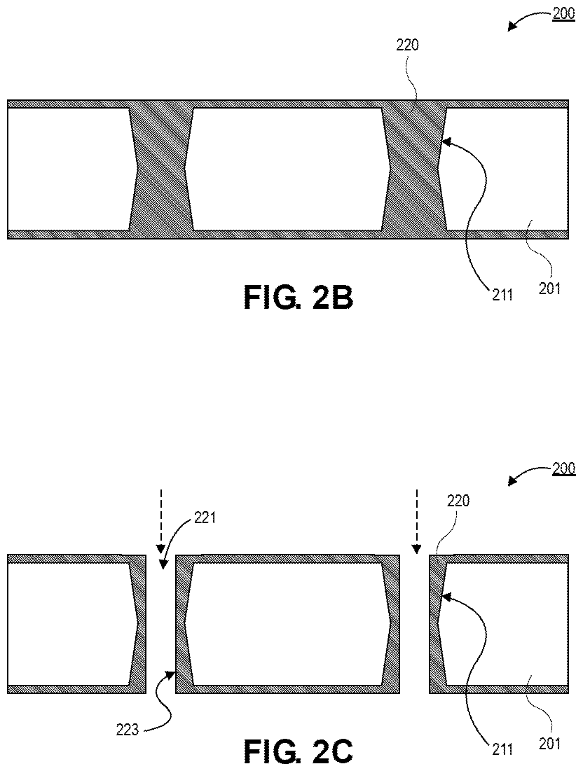

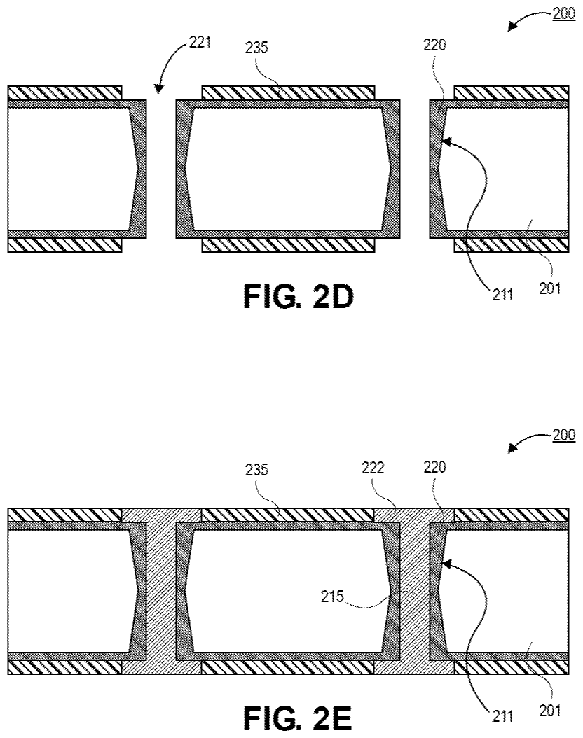

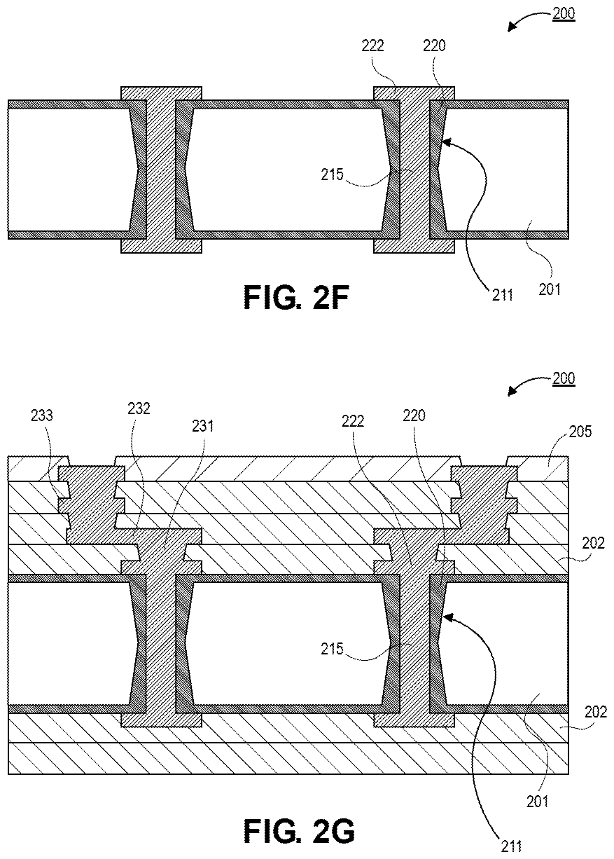

Referring now to FIGS. 2A-2G, a series of cross-sectional illustrations depicting a process for forming a package substrate 200 is shown, in accordance with an embodiment. In an embodiment, the package substrate 200 may be substantially similar to the package substrate 100 described above with respect to FIG. 1.

Referring now to FIG. 2A, a cross-sectional illustration of a package substrate 200 at a stage of manufacture is shown, in accordance with an embodiment. In an embodiment, the package substrate 200 may comprise a core 201. In a particular embodiment, the core 201 is a glass core, such as a borosilicate glass, a fused silica glass, or the like. Though other core 201 materials may be used in some embodiments. In an embodiment, the core 201 may have a thickness between approximately 100 μm and approximately 1,000 μm. In an embodiment, via openings 210 may be provided through a thickness of the core 201.

In the case of a glass core 201, the via openings 210 may be formed with a laser assisted patterning process. For example, a laser exposure may locally modify a microstructure or phase of the glass core 201. The modified regions are then more susceptible to an etching chemistry, such as a wet etch. The via openings 210 may have sidewalls 211 that are sloped. For example, the sidewalls 211 may provide a via opening 210 that has an hourglass shaped cross-section. The via openings 210 may be high aspect ratio features. For example, a width:depth ratio may be approximately 3:1 or greater, approximately 5:1 or greater, or approximately 10:1 or greater.

Referring now to FIG. 2B, a cross-sectional illustration of the package substrate 200 after an interface layer 220 is applied over the core 201 is shown, in accordance with an embodiment. In an embodiment, the interface layer 220 may comprise a composite material of a polymer and graphene particles. In an embodiment, the graphene particles may have a weight percentage of up to approximately 5 weight percent. The polymer may comprise one or more of a PI, a PET, a PA, a PANi, a PPy a PT, a PPP, a PEDOT, and the like. In an embodiment, the interface layer 220 may be applied with a lamination process, a squeegee process, or the like. The deposition process of the interface layer 220 may result in the via openings 210 being filled. The interface layer 220 may subsequently be cured (e.g., with a cure temperature up to approximately 400 degrees Celsius). In an embodiment, the interface layer 220 may be covalently bonded to the surface of the core 201 by silyl groups in order to improve adhesion. In other embodiments, the surfaces of the core 201 may be roughened using a swelling or etching process (e.g., with a permanganate and sodium hydroxide solution).

Referring now to FIG. 2C, a cross-sectional illustration of the package substrate 200 after openings 221 are formed in the interface layer 220 is shown, in accordance with an embodiment. In an embodiment, the openings 221 may be formed with a laser ablation process (as indicated by the dashed lines). The openings 221 may have substantially vertical sidewalls 223. In some embodiments, the sidewalls 223 of the openings 221 may have a profile that is different than the profile of the sidewalls 211. Though, in other embodiments, the openings 221 may also have sloped sidewalls 223 or an hourglass shaped profile.

Referring now to FIG. 2D, a cross-sectional illustration of the package substrate 200 after a resist layer 235 is provided over the interface layer 220 is shown, in accordance with an embodiment. In an embodiment, the resist layer 235 may be a dry film resist (DFR) or the like. In an embodiment, the resist layer 235 may be patterned to provide openings that align with the openings 221 in the interface layer 220. The openings in the resist layer 235 may be wider than the openings 221 in order to provide a pad above and below the resulting vias.

Referring now to FIG. 2E, a cross-sectional illustration of the package substrate 200 after a plating process is shown, in accordance with an embodiment. In an embodiment, the plating process may be an electroplating process. Due to the presence of the graphene particles in the interface layer 220, the electroplating can occur without the need for a separate seed layer. That is, the conductive features (i.e., vias 215 and pads 222) can be plated directly on the interface layer 220. Further, it is to be appreciated that in the case of traditional plating with a seed layer, the vias and pads would be characterized by a seed layer with a first composition and a bulk material with a second composition. In the case shown in FIG. 2E, the vias 215 and the pads 222 may have a single composition through their entire thickness (e.g., entirely copper).

In an embodiment, the vias 215 may be fully plated. That is, there may not be any voids or an air core within the vias 215. This improves reliability of the package substrate 200. In an embodiment, the vias 215 may be considered high aspect ratio features. For example, a depth:width ratio of the vias 215 may be approximately 3:1 or greater, approximately 5:1 or greater, or approximately 10:1 or greater. High aspect ratios with complete filling are enabled because the interface layer 220 fully covers an entire depth of the openings 221.

Referring now to FIG. 2F, a cross-sectional illustration of the package substrate 200 after the resist layer 235 is removed is shown, in accordance with an embodiment. The resist layer 235 may be removed with a resist stripping process, an etching process, or the like. As shown, portions of the interface layer 220 remain over the top and bottom surfaces of the core 201. However, the electrically insulating nature of the interface layer 220 allows for the pads 222 to remain electrically isolated from each other. As such, the interface layer 220 may persist into the final structure. This is an advantage over the use of seed layers, which require a seed etching operation in order to electrically isolate features from each other.

Referring now to FIG. 2G, a cross-sectional illustration of the package substrate 200 after buildup layers 202 are formed over and under the core is shown, in accordance with an embodiment. The buildup layers 202 may comprise traditional buildup film or the like. In an embodiment, conductive features, such as vias 231, traces 232, and pads 233 may be fabricated in the buildup layers 202 using traditional patterning and plating processes. In an embodiment, a solder resist layer 205 with openings may be provided over the surface of the package substrate 200.

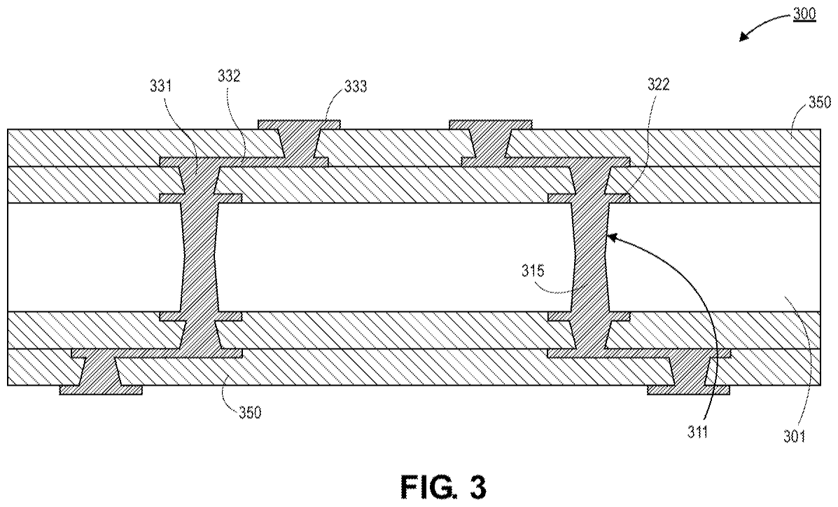

Referring now to FIG. 3, a cross-sectional illustration of a package substrate 300 is shown, in accordance with an embodiment. In an embodiment, the package substrate 300 may include a core 301. The core 301 may be a glass core or an organic core. For example, a glass core may comprise a borosilicate glass, a fused silica glass, or the like. In an embodiment, vias 315 may be provided through the core 301. The vias 315 may be plated with traditional plating processes (e.g., using a seed layer). In other embodiments, the vias 315 may be plated using an interface layer, similar to the embodiment shown in FIGS. 2A-2G. Pads 322 may be provided over and under the vias 315.

In an embodiment, the package substrate 300 may further include buildup layers 350 above and below the core 301. The buildup layers 350 may comprise a composite material that enables direct electroplating without a seed layer. For example, the buildup layers 350 may comprise a polymer with graphene fillers. The polymer may include one or more of a PI, a PET, a PA, a PANi, a PPy a PT, a PPP, a PEDOT, and the like. In an embodiment, the graphene fillers may have a weight percent that is up to approximately 5 weight percent of the composite. In an embodiment, conductive features, such as vias 331, traces 332, and pads 333 may be provided on the buildup layers 350. The buildup layers 350 allow for direct electroplating, but remain electrically insulating to enable electrical isolation of features. Further, the composite material of the buildup layers 350 may have a dielectric constant and CTE that is similar to existing organic buildup film materials.

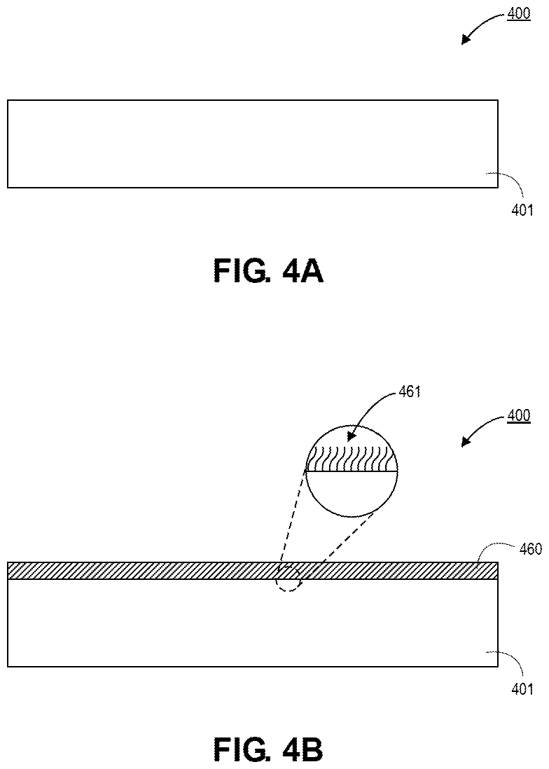

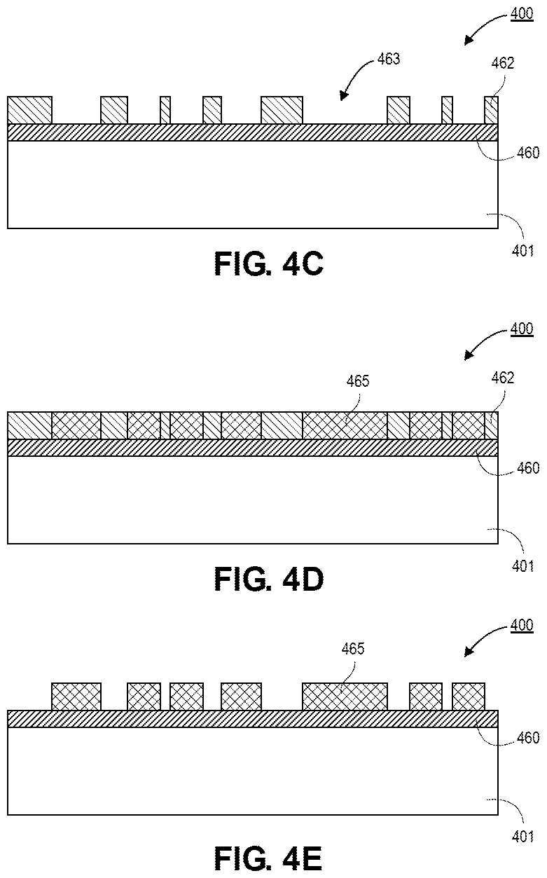

Referring now to FIGS. 4A-4E, a series of cross-sectional illustrations depicting a process for forming a package substrate 400 is shown, in accordance with an embodiment. In an embodiment, the package substrate 400 includes an interface layer 460 that allows for direct electroplating without a seed layer.

Referring now to FIG. 4A, a cross-sectional illustration of a package substrate 400 at a stage of manufacture is shown, in accordance with an embodiment. In an embodiment, the package substrate 400 comprises a substrate 401. The substrate 401 may be a glass core or an organic core. A glass core may comprise a borosilicate glass, a fused silica glass, or the like. In an embodiment, the substrate 401 may have a thickness that is between approximately 100 μm and approximately 1,000 μm. Alternatively, the substrate 401 may be a buildup layer, such as an organic buildup film, a polymer, or the like. In such instances, the substrate 401 may have a thickness between approximately 5 μm and approximately 30 μm.

Referring now to FIG. 4B, a cross-sectional illustration of the package substrate 400 after an interface layer 460 is deposited over a surface of the substrate 401 is shown, in accordance with an embodiment. In an embodiment, the interface layer 460 may comprise a layer of carbon nanotubes 461, as shown in the zoomed in portion of FIG. 4B. The carbon nanotubes 461 may be welded to the surface of the substrate 401. For example, microwave heating or a laser process may be used in order to weld the carbon nanotubes 461 to the surface of the substrate 401. The carbon nanotubes 461 may be applied to the surface of the substrate 401 using a spin-on process, a dip-coating process, a spraying process, a slit-coating process, using a self-assembled process, or a printing process.

The high electrical conductivity of carbon nanotubes enable electroplating and formation of a metal layer. In some embodiments, single walled carbon nanotubes may be formed through injecting floating catalyst chemical vapor deposition methods. The interface layer 460 may also be treated with a nitric acid in some embodiments in order to further lower the sheet resistance.

Referring now to FIG. 4C, a cross-sectional illustration of the package substrate 400 after a resist layer 462 is applied over the interface layer 460 is shown, in accordance with an embodiment. In an embodiment, the resist layer 462 may be a DFR or the like. The resist layer 462 may be patterned with a plurality of openings 463 that exposes the underlying interface layer 460.

Referring now to FIG. 4D, a cross-sectional illustration of the package substrate 400 after a plating process is implemented is shown, in accordance with an embodiment. The plating process may result in the formation of conductive features 465 over the interface layer 460. Particularly, it is noted that there is no need for an intervening seed layer between the conductive features 465 and the interface layer 460.

Referring now to FIG. 4E, a cross-sectional illustration of the package substrate 400 after the resist layer 462 is removed is shown, in accordance with an embodiment. The resist layer 462 may be removed with a resist stripping or etching process. In an embodiment, the removal of the resist layer 462 provides a plurality of electrically isolated conductive features 465. Particularly, the interface layer 460 does not electrically couple the conductive features 465 together, as a seed layer would. As such, the interface layer 460 may persist into the final structure.

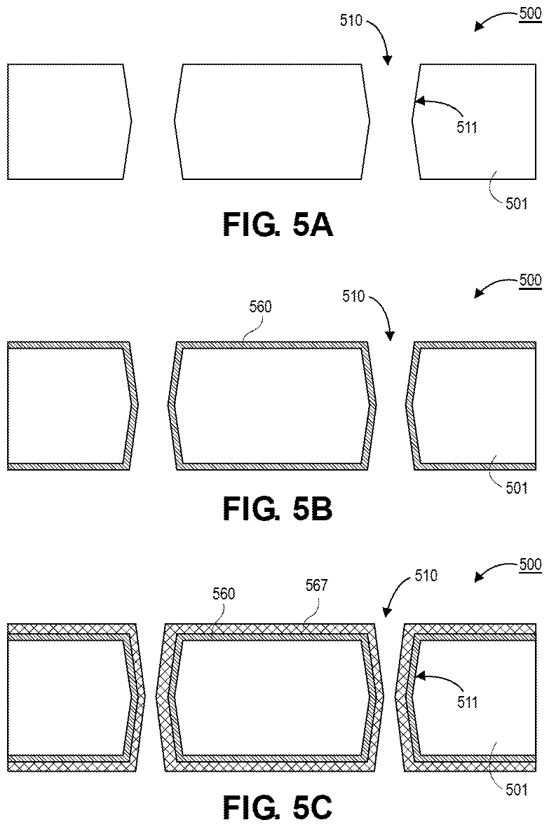

Referring now to FIGS. 5A-5C, a series of cross-sectional illustrations depicting a process for forming vias through a core 501 is shown, in accordance with an embodiment. In an embodiment, the vias may be formed with an interface layer 560 that includes welded carbon nanotubes.

Referring now to FIG. 5A, a cross-sectional illustration of package substrate 500 at a stage of manufacture is shown, in accordance with an embodiment. In an embodiment, the package substrate 500 may comprise a core 501, such as a glass core 501 comprising a borosilicate glass, a fused silica glass, or the like. In an embodiment, via openings 510 are provided through a thickness of the core 501. The via openings 510 may have sloped sidewalls 511. In an embodiment, the via openings 510 may have an hourglass shaped cross-section. The via openings 510 may be high aspect ratio features. For example, the aspect ratio may be 3:1 or greater, 5:1 or greater, or 10:1 or greater.

Referring now to FIG. 5B, a cross-sectional illustration of the package substrate 500 after an interface layer 560 is formed over exposed surfaces of the core 501 is shown, in accordance with an embodiment. In an embodiment, the interface layer 560 may be a layer of carbon nanotubes that are welded to the surfaces of the core 501. The interface layer 560 may be substantially similar to the interface layer 460 described in greater detail above, and may be deposited with similar processes. As shown, the interface layer 560 uniformly coats the sidewalls 511 of the via openings 510.

Referring now to FIG. 5C, a cross-sectional illustration of the package substrate 500 after a portion of the conductive layer 567 is plated is shown, in accordance with an embodiment. In an embodiment, the conductive layer 567 may be directly plated over the interface layer 560 with an electroplating process. That is, there may not be a seed layer between the interface layer 560 and the conductive layer 567. The conductive layer 567 may comprise copper or the like. In an embodiment, the conductive layer 567 may plate in the via openings 510. After further plating, the via openings 510 may be substantially fully filled with the conductive layer 567 in order to form solid vias. While shown without any masking from resist layers, it is to be appreciated that portions of the top and bottom surface of the package substrate 500 may be masked in order to form electrically isolated conductive features.

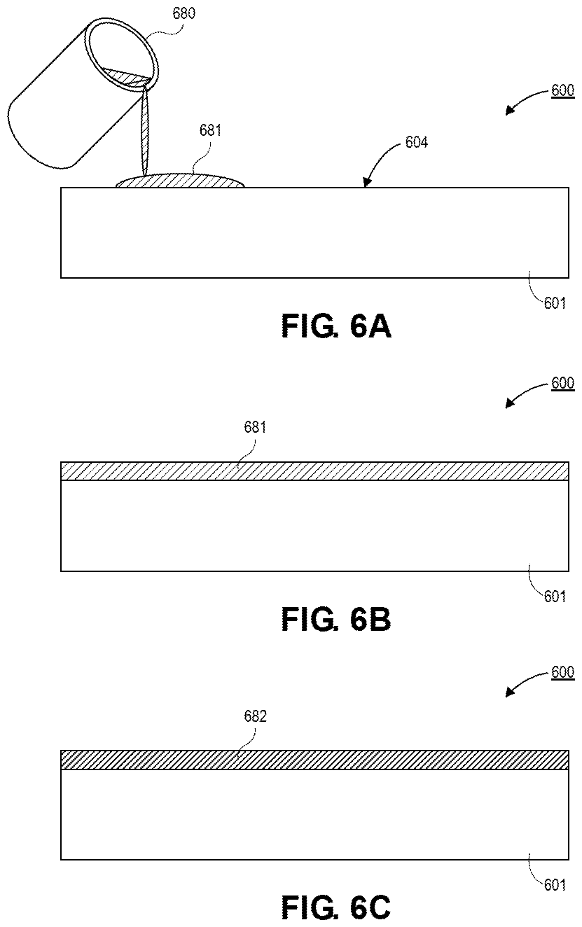

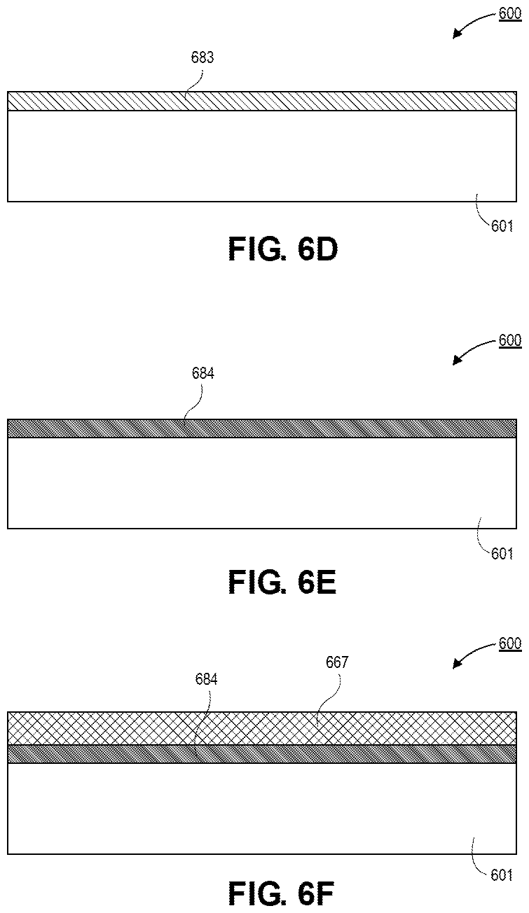

Referring now to FIGS. 6A-6F, a series of cross-sectional illustrations depicting a process for forming a package substrate 600 is shown, in accordance with an embodiment. The package substrate 600 may include an interface layer that is formed with a sol-gel process. The conductive features may then be plated directly from the interface layer without a seed layer.

Referring now to FIG. 6A, a cross-sectional illustration of a package substrate 600 at a stage of manufacture is shown, in accordance with an embodiment. In an embodiment, the package substrate 600 may include a core 601, such as a glass core 601 that includes a borosilicate glass, a fused silica glass, or the like. In an embodiment, the core 601 may have a thickness between approximately 100 μm and approximately 1,000 μm. In an embodiment, a mixture 681 of carbon nanotubes and metal-alkoxides (e.g., TiO₂, ZnO, Al₂O₃, and the like) may be dispensed onto a surface 604 of the core 601 from a container 680. Any deposition process may be used, such as a dip process, a spray process, or a spin coating process. Additives may also be provided in the mixture 681 in some embodiments.

Referring now to FIG. 6B, a cross-sectional illustration of the package substrate 600 after the mixture 681 is spread across the surface 604 of the substrate 601 is shown, in accordance with an embodiment. Any of the deposition processes described above may be used in order to form a substantially uniform layer of the mixture over the surface 604 of the core 601.

Referring now to FIG. 6C, a cross-sectional illustration of the package substrate 600 after the mixture is processed to form a sol 682 is shown, in accordance with an embodiment. In an embodiment, the sol 682 may be formed by a hydrolyzing process and a condensation process.

Referring now to FIG. 6D a cross-sectional illustration of the package substrate 600 after a xerogel 683 is formed is shown, in accordance with an embodiment. The processing may include a treatment of the sol 682 in order to produce the xerogel 683. For example, the treatment may be a heat treating operation.

Referring now to FIG. 6E, a cross-sectional illustration of the package substrate 600 after a ceramic composite 684 is formed from the xerogel 683 is shown, in accordance with an embodiment. In an embodiment, the ceramic composite 684 may be formed by sintering the xerogel 683. For example a laser sintering process that increases the temperature of the xerogel 683 to a temperature between approximately 400 degrees Celsius and approximately 600 degrees Celsius may be used in some embodiment. The resulting ceramic composite 684 includes metal alkoxides and carbon nanotubes.

Referring now to FIG. 6F, a cross-sectional illustration of the package substrate 600 after a conductive layer 667 (e.g., copper) is provided over the ceramic composite 684 is shown, in accordance with an embodiment. In an embodiment, the conductive layer 667 is plated with an electroplating process. Particularly, there is no need for a seed layer between the ceramic composite 684 and the conductive layer 667 due to the presence of electrically conductive carbon nanotubes.

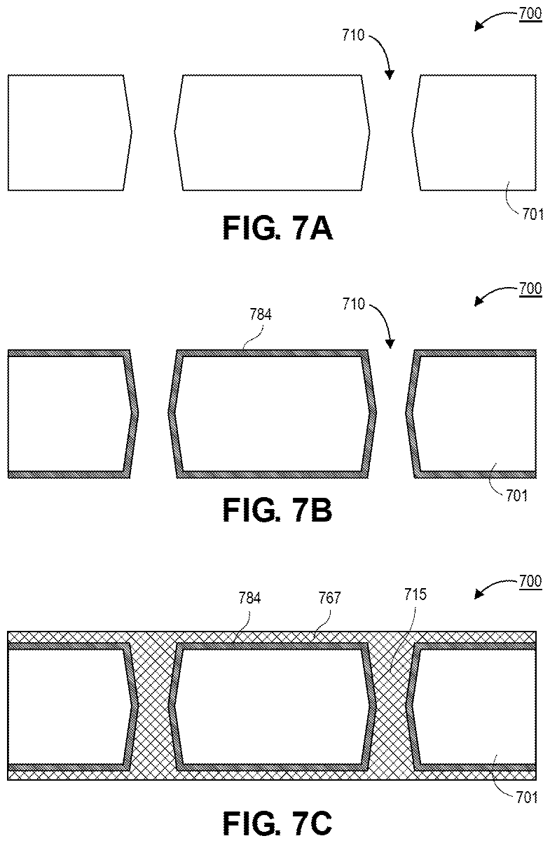

Referring now to FIGS. 7A-7C, a series of cross-sectional illustrations depicting a process for forming a package substrate 700 that includes a core with vias 715 is shown, in accordance with an embodiment. In an embodiment, the conductive features 767 and vias 715 may be directly plated from a ceramic composite 784.

Referring now to FIG. 7A, a cross-sectional illustration of a package substrate 700 at a stage of manufacture is shown, in accordance with an embodiment. The package substrate 700 may comprise a core 701. In an embodiment, the core 701 may comprise glass, such as a borosilicate glass, a fused silica glass, or the like. Via openings 710 may be provided in the core 701. The via openings 710 may have sloped sidewalls. For example, the via opening 710 may be hourglass shaped in some embodiments. The via openings 710 may be high aspect ratio features. For example, the via openings 710 may have an aspect ratio of 3:1 or greater, 5:1 or greater, or 10:1 or greater.

Referring now to FIG. 7B, a cross-sectional illustration of the package substrate 700 after a ceramic composite 784 is formed over the exposed surfaces of the core 701 is shown, in accordance with an embodiment. The ceramic composite 784 may be formed with processes similar to the process described above to form the ceramic composite 684. For example, a sol-gel process may be used to form the ceramic composite 784. The ceramic composite 784 may comprise metal alkoxides and carbon nanotubes in some embodiments.

Referring now to FIG. 7C, a cross-sectional illustration of the package substrate 700 after conductive features 767 and vias 715 are formed is shown, in accordance with an embodiment. In an embodiment, the conductive features 767 and the vias 715 may be plated up using an electroplating process. For example, the conductive features 767 and vias 715 may comprise copper. There may be no need for an intervening seed layer between the conductive features 767 and the ceramic composite 784 or between the vias 715 and the ceramic composite 784.

It is to be appreciated that any of the embodiments that are used to form vias through a core without a seed layer may also be used to form buildup layers over and under the core. The buildup layers with embodiments disclosed herein allow for direct plating without a seed layer. Further, the dielectric properties of such layers are similar to those of traditional buildup films, and therefore provide consistent performance to existing packages. For example, carbon nanotubes that are welded to the surface may be used as at least part of the buildup film, or ceramic composites with carbon nanotubes and alkoxides may be used as at least part of the buildup film.

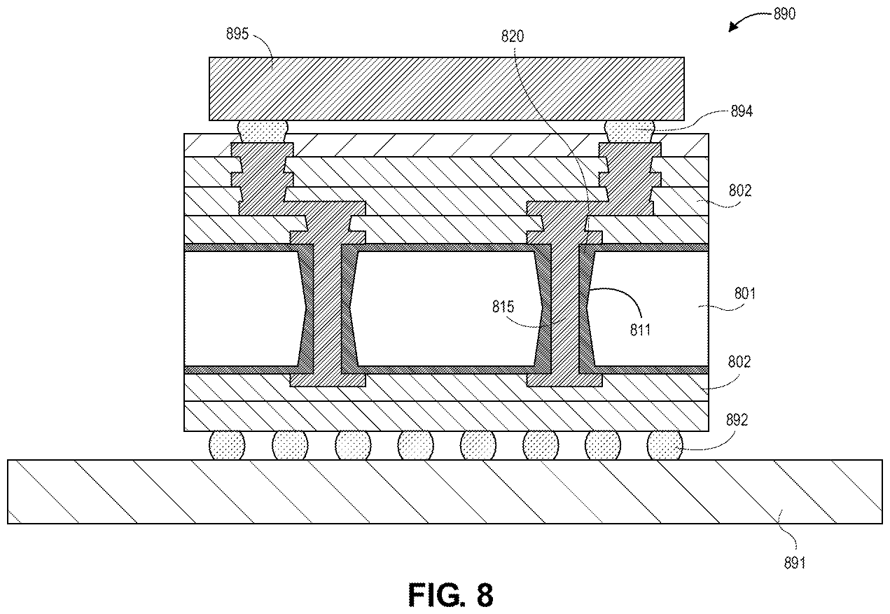

Referring now to FIG. 8, a cross-sectional illustration of a computing system 890 is shown, in accordance with an embodiment. In an embodiment, the computing system 890 may comprise a board 891, such as a printed circuit board (PCB). The board 891 may be coupled to a package substrate by interconnects 892. While shown as solder balls, it is to be appreciated that interconnects 892 may include any interconnect architecture (e.g., sockets or the like).

In an embodiment, the package substrate comprises a core 801. The core 801 may be a glass core or an organic core. Glass cores 801 may comprise a borosilicate glass, a fused silica glass, or the like. Buildup layers 802 may be provided over and under the core 801. In an embodiment, the core 801 may include vias 815. The vias 815 may be separated from the core 801 by an interface layer 820. The interface layer 820 may be similar to any of the interface layers described in greater detail herein. For example, the interface layer 820 may comprise a polymer and graphene particles, welded carbon nanotubes, or a ceramic composite including metal alkoxides and carbon nanotubes. The interface layer 820 allows for electroplating the vias 815 without the need of a seed layer. In the illustrated embodiment, the package substrate is shown as being similar to the package substrate 100 in FIG. 1. Though, it is to be appreciated that the package substrate in FIG. 8 may be similar to any of the package substrates described in greater detail herein.

In an embodiment, one or more dies 895 may be coupled to the package substrate by interconnects 894. The interconnects 894 may be any suitable first level interconnect (FLI) architecture. The dies 895 may comprise compute dies, such as a central processing unit (CPU), a graphics processing unit (GPU), an XPU, a system on a chip (SoC), an application specific integrated circuit (ASIC), or the like. The dies 895 may also comprise memory dies in some instances.

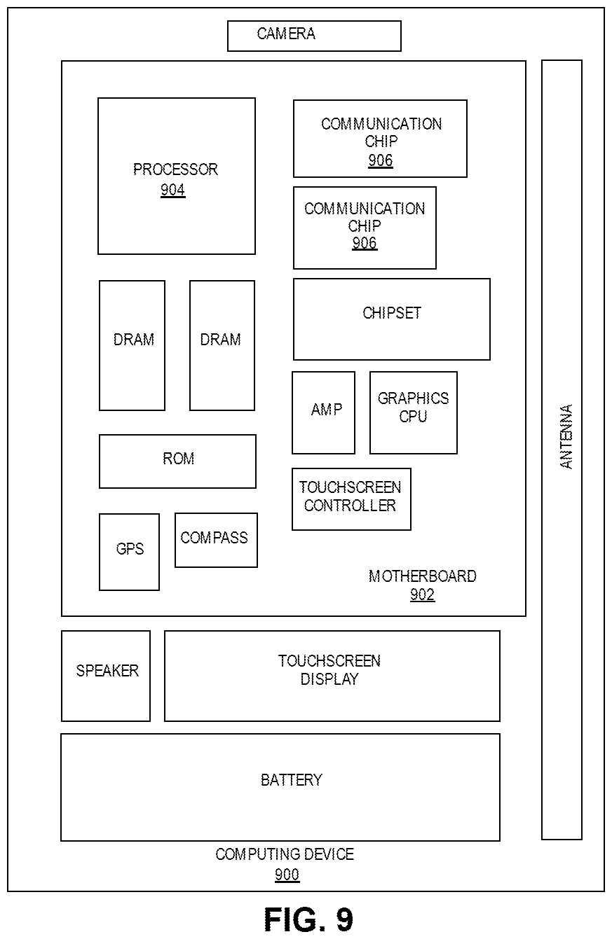

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic package that comprises a core with an interface layer that allows for direct electroplating without the need for an intervening seed layer, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of an electronic package that comprises a core with an interface layer that allows for direct electroplating without the need for an intervening seed layer, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a core; a via opening through the core, wherein the via opening comprises sidewalls; a composite layer along the sidewalls, wherein the composite layer comprises carbon; and a via within the via opening, wherein the via is electrically conductive.

Example 2: the package substrate of Example 1, wherein the composite layer comprises a polymer, and wherein the carbon comprises graphene that is distributed through the polymer.

Example 3: the package substrate of Example 2, wherein the polymer comprises a polyimide (PI), a polyethylene terephthalate (PET), a polyacetylene (PA), a polyaniline (PANi), a polypyrrole (PPy) a polythiophene (PT), a poly(p-phenylene) (PPP), or a poly(3,4-ethylene dioxythiophene) (PEDOT).

Example 4: the package substrate of Examples 1-3, wherein the sidewalls have a slope.

Example 5: the package substrate of Example 4, wherein the sidewalls define a via opening with an hourglass shaped cross-section.

Example 6: the package substrate of Example 5, wherein interior sidewalls of the composite layer are substantially vertical.

Example 7: the package substrate of Examples 1-6, wherein the core comprises glass.

Example 8: the package substrate of Examples 1-7, wherein the composite layer is over a top surface and a bottom surface of the core.

Example 9: the package substrate of Examples 1-8, wherein the carbon comprises up to approximately 5 weight percent of the composite.

Example 10: the package substrate of Examples 1-9, wherein silyl groups are provided between the sidewalls and the composite layer.

Example 11: a package substrate, comprising: a core; buildup layers over the core, wherein the buildup layers comprise a composite material that includes graphene particles; and conductive routing on the buildup layers, wherein the conductive routing is directly formed over the composite material without an intervening seed layer.

Example 12: the package substrate of Example 11, wherein the composite material comprises a polymer, and wherein the graphene particles are distributed in the polymer.

Example 13: the package substrate of Example 12, wherein the polymer comprises a polyimide (PI), a polyethylene terephthalate (PET), a polyacetylene (PA), a polyaniline (PANi), a polypyrrole (PPy) a polythiophene (PT), a poly(p-phenylene) (PPP), or a poly(3,4-ethylene dioxythiophene) (PEDOT).

Example 14: the package substrate of Examples 11-13, wherein the package substrate is part of a computing system for a personal computer, a server, a mobile device, a tablet, or an automobile.

Example 15: a package substrate, comprising: a core; a carbon nanotube layer attached to the core or an interface layer over the core, wherein the interface layer comprises a carbon nanotube doped metal alkoxide; and a layer over the carbon nanotube layer or the interface layer, wherein the layer is electrically conductive.

Example 16: the package substrate of Example 15, wherein the carbon nanotube layer is welded to the core.

Example 17: the package substrate of Example 15 or Example 16, further comprising: a via opening through the core, wherein the carbon nanotube layer lines the via opening, and wherein the layer fills the via opening.

Example 18: the package substrate of Example 15, wherein a via opening is formed through the core, wherein the interface layer lines the via opening, and wherein the layer fills the via opening.

Example 19: the package substrate of Examples 15-18, further comprising: a die coupled to the package substrate; and a board coupled to the package substrate.

Example 20: the package substrate of Example 19, wherein the package substrate is part of a computing system for a personal computer, a server, a tablet, a mobile device, or an automobile.

What is claimed is:

1. A package substrate, comprising:
a core;
a via opening through the core, wherein the via opening comprises sidewalls;
a composite layer along the sidewalls, wherein the composite layer comprises carbon; and
a via within the via opening, wherein the via is electrically conductive.

2. The package substrate of claim 1, wherein the composite layer comprises a polymer, and wherein the carbon comprises graphene that is distributed through the polymer.

3. The package substrate of claim 2, wherein the polymer comprises a polyimide (PI), a polyethylene terephthalate (PET), a polyacetylene (PA), a polyaniline (PANi), a polypyrrole (PPy) a polythiophene (PT), a poly(p-phenylene) (PPP), or a poly(3,4-ethylene dioxythiophene) (PEDOT).

4. The package substrate of claim 1, wherein the sidewalls have a slope.

5. The package substrate of claim 4, wherein the sidewalls define a via opening with an hourglass shaped cross-section.

6. The package substrate of claim 5, wherein interior sidewalls of the composite layer are substantially vertical.

7. The package substrate of claim 1, wherein the core comprises glass.

8. The package substrate of claim 1, wherein the composite layer is over a top surface and a bottom surface of the core.

9. The package substrate of claim 1, wherein the carbon comprises up to approximately 5 weight percent of the composite.

10. The package substrate of claim 1, wherein silyl groups are provided between the sidewalls and the composite layer.

11. A package substrate, comprising:
a core;
buildup layers over the core, wherein the buildup layers comprise a composite material that includes graphene particles; and
conductive routing on the buildup layers, wherein the conductive routing is directly formed over the composite material without an intervening seed layer.

12. The package substrate of claim 11, wherein the composite material comprises a polymer, and wherein the graphene particles are distributed in the polymer.

13. The package substrate of claim 12, wherein the polymer comprises a polyimide (PI), a polyethylene terephthalate (PET), a polyacetylene (PA), a polyaniline (PANi), a polypyrrole (PPy) a polythiophene (PT), a poly(p-phenylene) (PPP), or a poly(3,4-ethylene dioxythiophene) (PEDOT).

14. The package substrate of claim 11, wherein the package substrate is part of a computing system for a personal computer, a server, a mobile device, a tablet, or an automobile.

15. A package substrate, comprising:
a core;
a carbon nanotube layer attached to the core or an interface layer over the core, wherein the interface layer comprises a carbon nanotube doped metal alkoxide; and
a layer over the carbon nanotube layer or the interface layer, wherein the layer is electrically conductive.

16. The package substrate of claim 15, wherein the carbon nanotube layer is welded to the core.

17. The package substrate of claim 15, further comprising:
a via opening through the core, wherein the carbon nanotube layer lines the via opening, and wherein the layer fills the via opening.

18. The package substrate of claim 15, wherein a via opening is formed through the core, wherein the interface layer lines the via opening, and wherein the layer fills the via opening.

19. The package substrate of claim 15, further comprising:
a die coupled to the package substrate;
a board coupled to the package substrate;

20. The package substrate of claim 19, wherein the package substrate is part of a computing system for a personal computer, a server, a tablet, a mobile device, or an automobile.
